(19) United States
(12) Patent Application Publication
(10) Pub. No.: US 2018/0149934 A1
(43) Pub. Date: May 31, 2018

(54) ARRAY SUBSTRATE AND LIQUID CRYSTAL DISPLAY PANEL

(71) Applicant: SHENZHEN CHINA STAR OPTOELECTRONICS TECHNOLOGY CO., LTD., Shenzhen (CN)

(72) Inventor: Meng WANG, Shenzhen (CN)

(73) Assignee: SHENZHEN CHINA STAR OPTOELECTRONICS TECHNOLOGY CO., LTD., Shenzhen (CN)

(21) Appl. No.: 15/124,365

(22) PCT Filed: May 23, 2016
(86) PCT No.: PCT/CN2016/082951

§ 371 Date: Sep. 8, 2016

(30) Foreign Application Priority Data
Apr. 5, 2016 (CN) 201610207446.0

(51) Int. Cl. G02F 1/1362; H01L 29/786; G02F 1/1368

(52) U.S. Cl. CPC G02F 1/136209; H01L 29/78633; G02F 1/1368; H01L 29/78618; H01L 27/1225; G02F 2201/123; G02F 2202/10; H01L 29/7869; G02F 2201/124

(57) ABSTRACT

An array substrate and a liquid crystal display panel are provided. The array substrate includes a base substrate, a first metal layer, a gate insulating layer, an active layer, a second metal layer, a first insulating layer, and a third metal layer. The active layer is used for forming a channel. The second metal layer includes a drain region and a source region of the thin film transistor. The third metal layer includes a light protection region. The position of the light protection region corresponds to the position of the channel.

### FIELD OF THE INVENTION

The present invention relates to a field of displays, and in particular to an array substrate and a liquid crystal display panel.

### BACKGROUND OF THE INVENTION

A conventional liquid crystal display (LCD) panel includes an array substrate and a color filter substrate. A thin film transistor is disposed on the array substrate, and includes gate electrodes, source electrodes, drain electrodes, and an active layer (for forming channels). The material of the active layer is an oxide semiconductor material.

Ultraviolet radiation is unavoidably used in a conventional LCD panel manufacture process. When the oxide semiconductor material is irradiated by ultraviolet radiation, the charging performance of the thin film transistor is reduced. The charging performance of the thin film transistor before the irradiation is as shown in FIG. 1. The charging performance of the thin film transistor after the irradiation is as shown in FIG. 2. In FIG. 1 and FIG. 2, the horizontal axis indicates voltage, and the vertical axis indicates capacitance. Comparing the two figures, it is not difficult to find that the threshold voltage of the thin film transistor reduces; that is, the charging performance decreases, and the display effect lowers.

Therefore, it is necessary to provide an array substrate and a liquid crystal display panel to resolve the problem of the prior art.

### SUMMARY OF THE INVENTION

A primary object of the present invention is to provide an array substrate and a liquid crystal display panel to resolve the technical problem that the channel of the thin film transistor exposed to the ultraviolet radiation causes the charging performance to decrease and the display effect to lower.

To resolve the above technical problem, the present invention provides an array substrate, comprising:

a base substrate;

a first metal layer disposed on the base substrate and including a gate region of a thin film transistor;

a gate insulating layer disposed on the first metal layer for separating the first metal layer from a second metal layer;

an active layer, a part of which is disposed on the gate insulating layer for forming a channel;

an ohmic contact layer disposed on the active layer;

the second metal layer disposed on the ohmic contact layer and including a drain region and a source region of the thin film transistor;

a first insulating layer disposed on the second metal layer; and

a third metal layer disposed on the first insulating layer and including a light protection region, wherein a position of the light protection region corresponds to a position of the channel, and an area of the light protection region projected on the base substrate is slightly larger than an area of the channel projected on the base substrate.

In the array substrate of the present invention, the third metal layer further includes a pixel electrode, and the light protection region, and the pixel electrode are obtained in a processing step.

The array substrate of the present invention further comprises a transparent conductive layer disposed on the third metal layer and including a pixel electrode.

The array substrate of the present invention further comprises a flat layer disposed on the third metal layer.

In the array substrate of the present invention, a material of the ohmic contact layer is silicon nitride.

To resolve the above technical problem, the present invention provides an array substrate, comprising:

a base substrate;

a first metal layer disposed on the base substrate and including a gate region of a thin film transistor;

a gate insulating layer disposed on the first metal layer for separating the first metal layer from a second metal layer;

an active layer, a part of which is disposed on the gate insulating layer for forming a channel;

the second metal layer disposed on the active layer and including a drain region and a source region of the thin film transistor;

a first insulating layer disposed on the second metal layer; and

a third metal layer disposed on the first insulating layer and including a light protection region, wherein a position of the light protection region corresponds to a position of the channel.

In the array substrate of the present invention, the third metal layer further includes a pixel electrode, and the light protection region and the pixel electrode are obtained in a processing step.

The array substrate of the present invention further comprises a transparent conductive layer disposed on the third metal layer and including a pixel electrode.

In the array substrate of the present invention, an area of the light protection region projected on the base substrate is slightly larger than an area of the channel projected on the base substrate.

The array substrate of the present invention further comprises a flat layer disposed on the third metal layer.

The array substrate of the present invention further comprises an ohmic contact layer disposed between the active layer and the second metal layer.

In the array substrate of the present invention, a material of the ohmic contact layer is silicon nitride.

The present invention also provides a liquid crystal display panel, comprising:

a color filter substrate disposed opposite an array substrate;

a liquid crystal layer disposed between the color filter substrate and the array substrate, and

the array substrate including:

a base substrate;

a first metal layer disposed on the base substrate and including a gate region of a thin film transistor;

a gate insulating layer disposed on the first metal layer for separating the first metal layer from a second metal layer;

an active layer, a part of which is disposed on the gate insulating layer for forming a channel;

the second metal layer disposed on the active layer and including a drain region and a source region of the thin film transistor;

a first insulating layer disposed on the second metal layer; and

a third metal layer disposed on the first insulating layer and including a light protection region, wherein a position of the light protection region corresponds to a position of the channel.

In the liquid crystal display panel, the third metal layer further includes a pixel electrode, and the light protection region and the pixel electrode are obtained in a processing step.

The liquid crystal display panel further comprises a transparent conductive layer disposed on the third metal layer and including a pixel electrode.

In the liquid crystal display panel, an area of the light protection region projected on the base substrate is slightly larger than an area of the channel projected on the base substrate.

The liquid crystal display panel further comprises a flat layer disposed on the third metal layer.

The liquid crystal display panel further comprises an ohmic contact layer disposed between the active layer and the second metal layer.

In the liquid crystal display panel, a material of the ohmic contact layer is silicon nitride.

Since the light protection region is disposed over the position corresponding to the channel, the array substrate and the liquid crystal display panel prevent the channel from exposure to ultraviolet radiation and improve the charging performance and the display effect.

### BRIEF DESCRIPTION OF THE DRAWINGS

FIG. 1 is a schematic diagram of the charging performance of the thin film transistor before exposure in a prior art;

FIG. 2 is a schematic diagram of the charging performance of the thin film transistor after exposure in a prior art;

FIG. 3 is a structural schematic diagram of the array substrate in accordance with the present invention; and

FIG. 4 is a top view of the array substrate in accordance with the present invention.

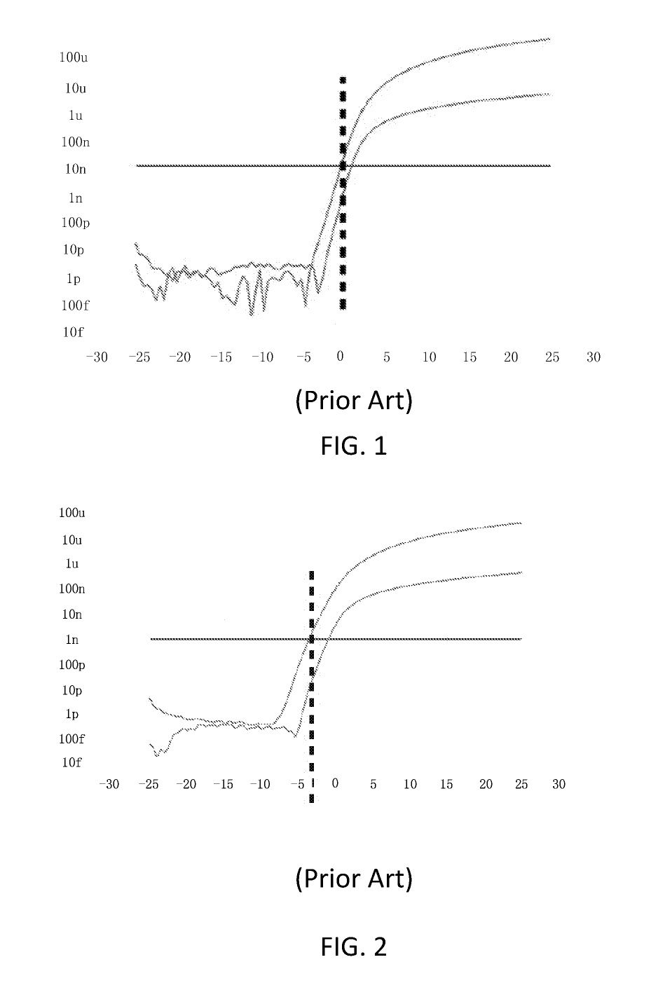

### DETAILED DESCRIPTION OF THE PREFERRED EMBODIMENTS

The following description of the embodiments with reference to the accompanying drawings is used to illustrate particular embodiments of the present invention. The directional terms referred in the present invention, such as “upper”, “lower”, “front”, “back”, “left”, “right”, “inner”, “outer”, “side surface”, etc. are only directions with regard to the accompanying drawings. Therefore, the directional terms used for describing and illustrating the present invention are not intended to limit the present invention.

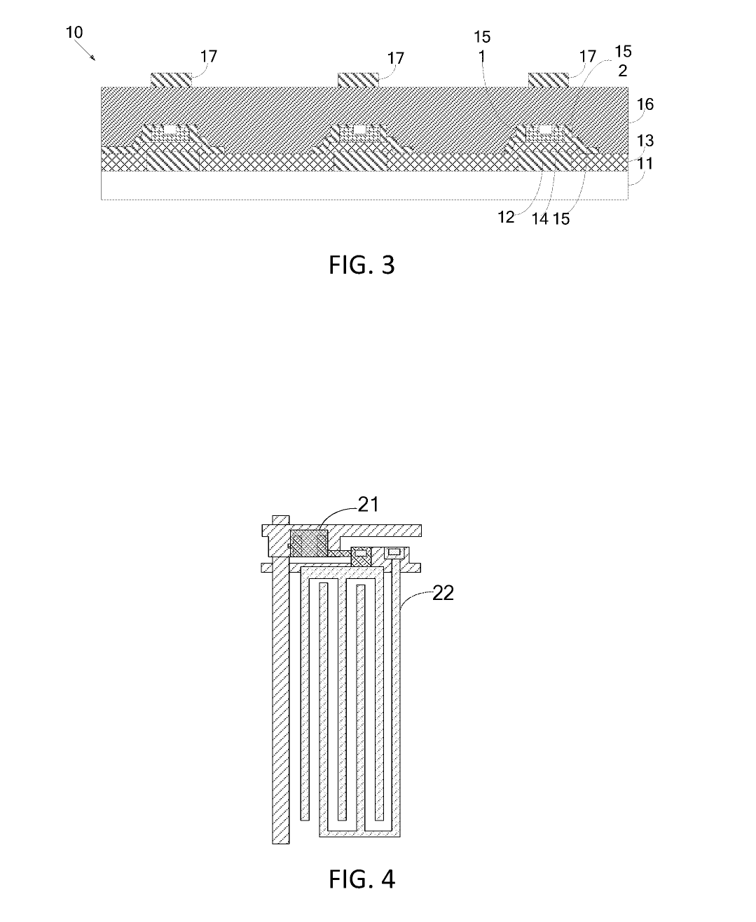

Please refer to FIG. 3, which is a structural schematic diagram of an array substrate in accordance with the present invention.

The array substrate 10 of the present invention, as shown in FIG. 3, includes a base substrate 11, a first metal layer 12, a gate insulating layer 13, an active layer 14, a second metal layer 15, a first insulating layer 16, and a third metal layer 17, and may also include an ohmic contact layer (not shown in the figure).

The first metal layer 12 is disposed on the base substrate 11, and includes the gate region of a thin film transistor. The first metal layer 12 undergoes a patterning process to form gate electrodes. The portion of the first metal layer outside the gate region is etched off during a manufacturing process. The first metal layer 12 may be chromium, molybdenum, aluminum, copper, etc.

In order to separate the first metal layer 12 from the second metal layer 15, and separate the first metal layer 12 from the active layer 14, the gate insulating layer 13 is disposed on the first metal layer 12. Only the gate region of the first metal layer 12 is provided with the gate insulating layer 13, and the rest of the gate insulating layer 13 is disposed on the base substrate 11. A portion of the active layer 14 is disposed on the gate insulating layer 13 for forming a channel between the drain electrode and the source electrode of the thin film transistor.

The ohmic contact layer may be disposed on the active layer 14 for turning on the source electrodes and the drain electrodes when the gate electrodes of the thin film transistors are closed. The material of the ohmic contact layer may be silicon nitride.

The second metal layer 15 is disposed on the ohmic contact layer, and includes the drain regions 151 and the source regions 152 of the thin film transistors and data lines. The second metal layer 15 undergoes a patterning process for forming the drain electrodes 151, the source electrodes 152, and the data lines. The portion of the second metal layer outside the drain electrodes, the source electrodes, and the data lines is etched off during a manufacturing process.

The first insulating layer 16 is for separating the second metal layer 15 from the third metal layer 17, wherein the third metal layer 17 undergoes a patterning process to form a light protection region, and the position of the light protection region corresponds to the position of the channel; that is, the portion of the third metal layer 17 outside the position corresponding to the channel can be etched off, only leaving the light protection region.

Preferably, the area of the light protection region projected on the base substrate 11 is slightly larger the area of the channel projected on the base substrate; that is, with respect to the projection in the vertical direction, the area of the light protection region is larger than the area of the channel, thereby effectively preventing the channel from the irradiation by ultraviolet radiation.

In addition, on the basis of the existing array substrate, the first insulating layer 16 and the third metal layer 17 are additionally added, so as to increase the overall thickness of the array substrate, thereby reducing the parasitic capacitance and further improving the display effect.

The light protection region is used for preventing the channel from the irradiation by ultraviolet radiation, thereby preventing the charging performance of the thin film transistor from decrease.

It can be understood that the above structure can be applied in an FFS (fringe field switching) panel. When applied in an FFS panel, a transparent conductive layer can be manufactured on the third metal layer 17, and the transparent conductive layer includes pixel electrodes. The transparent conductive layer may be formed by a sputtering coating method, and the pixel electrodes and the drain electrodes are connected with each other through vias.

Of course, in order to improve the display effect of the liquid crystal display panel, a flat layer can be disposed on the transparent conductive layer. The smoother the surface of the array substrate is, more uniform the liquid crystal molecules diffuse, facilitating obtaining the more accurate optimal number of the liquid crystals during manufacturing the liquid crystal display panel (the number of the liquid crystals required for achieving the optimal display effect of the liquid crystal display panel).

It can be understood that, in order to further reduce the production cost, the above described structure can be applied in an IPS (In-Plane Switching) panel. When applied in an IPS panel as shown in FIG. 4, the third metal layer 17 undergoes a patterning process to form the light protection region 21 and the pixel electrodes 22, wherein the light protection region 21 is disposed over the channel. The pixel electrodes and the light protection region are prepared in the same manufacture process, thereby reducing the production cost. The pixel electrodes and the drain electrodes are connected with each other through a through hole.

In order to improve the display effect of the liquid crystal display panel, a flat layer can be disposed on the third metal layer 17. Preferably, a first alignment film can be disposed on the flat layer. Certainly, the array substrate further includes scan lines, and the data lines and the scan lines define the plurality of pixel units.

Since the light protection region is disposed over the position corresponding to the channel, the array substrate of the present invention prevents the channel from the irradiation by ultraviolet radiation and improves the charging performance of the thin film transistor.

The present invention further provides a liquid crystal display panel, including a color filter substrate, an array substrate, and a liquid crystal layer disposed between the color filter substrate and the array substrate. The color filter substrate can include a color resist layer and common electrodes. The array substrate 10 of the present invention, as shown in FIG. 3, includes a base substrate 11, a first metal layer 12, a gate insulating layer 13, an active layer 14, a second metal layer 15, a first insulating layer 16, and a third metal layer 17, and may also include an ohmic contact layer (not shown in the figure).

The first metal layer 12 is disposed on the base substrate 11, and includes the gate region of a thin film transistor. The first metal layer 12 undergoes a patterning process to form gate electrodes. The portion of the first metal layer outside the gate region is etched off during a manufacturing process. The first metal layer 12 may be chromium, molybdenum, aluminum, copper, etc.

In order to separate the first metal layer 12 from the second metal layer 15, and separate the first metal layer 12 from the active layer 14, the gate insulating layer 13 is disposed on the first metal layer 12. Only the gate region of the first metal layer 12 is provided with the gate insulating layer 13, the rest of the gate insulating layer 13 is disposed on the base substrate. A portion of the active layer 14 is disposed on the gate insulating layer 13 for forming a channel between the drain electrode and the source electrode of the thin film transistor.

The ohmic contact layer may be disposed on the active layer 14 for turning on the source electrodes and the drain electrodes when the gate electrodes of the thin film transistors are closed. The material of the ohmic contact layer may be silicon nitride.

The second metal layer 15 is disposed on the ohmic contact layer, and includes the drain regions 151 and the source regions 152 of the thin film transistors and data lines. The second metal layer 15 undergoes a patterning process for forming the drain electrodes 151, the source electrodes 152, and the data lines. The portion of the second metal layer outside the drain electrodes, the source electrodes, and the data lines is etched off during a manufacturing process.

The first insulating layer 16 is for separating the second metal layer 15 from the third metal layer 17, wherein the third metal layer 17 undergoes a patterning process to form a light protection region, and the position of the light protection region corresponds to the position of the channel; that is, the portion of the third metal layer 17 outside the position corresponding to the channel can be etched off, leaving only the light protection region.

Preferably, the area of the light protection region projected on the base substrate 11 is slightly larger the area of the channel projected on the base substrate; that is, with respect to the projection in the vertical direction, the area of the light protection region is larger than the area of the channel, thereby effectively preventing the channel from the irradiation by ultraviolet radiation.

In addition, on the basis of the existing array substrate, the first insulating layer 16 and the third metal layer 17 are additionally added, so as to increase the overall thickness of the array substrate, thereby reducing the parasitic capacitance and further improving the display effect.

The light protection region is used for preventing the channel from the irradiation by ultraviolet radiation, thereby preventing the charging performance of the thin film transistor from decrease.

It can be understood that the above structure can be applied in an FFS (fringe field switching) panel. When applied in an FFS panel, a transparent conductive layer can be manufactured on the third metal layer 17, and the transparent conductive layer includes pixel electrodes. The transparent conductive layer may be formed by a sputtering coating method, and the pixel electrodes and the drain electrodes are connected with each other through vias.

Of course, in order to improve the display effect of the liquid crystal display panel, a flat layer can be disposed on the transparent conductive layer. The smoother the surface of the array substrate is, more uniform the liquid crystal molecules diffuse, facilitating obtaining the more accurate optimal number of the liquid crystals during manufacturing the liquid crystal display panel (the number of the liquid crystals required for achieving the optimal display effect of the liquid crystal display panel).

It can be understood that, in order to further reduce the production cost, the above described structure can be applied in an IPS (In-Plane Switching) panel. When applied in an IPS panel as shown in FIG. 4, the third metal layer 17 undergoes a patterning process to form the light protection region 21 and the pixel electrodes 22, wherein the light protection region 21 is disposed over the channel. The pixel electrodes and the light protection region are prepared in the same manufacture process, thereby reducing the production cost. The pixel electrodes and the drain electrodes are connected with each other through vias.

In order to improve the display effect of the liquid crystal display panel, a flat layer can be disposed on the third metal layer 17. Preferably, a first alignment film can be disposed on the flat layer. Certainly, the array substrate further includes scan lines, and the data lines and the scan lines define the plurality of the pixel units.

Since the light protection region is disposed over the position corresponding to the channel, the array substrate of the present invention prevents the channel from the irradiation by ultraviolet radiation and improves the charging performance of the thin film transistor.

In summary, although the preferable embodiments of the present invention have been disclosed above, the embodiments are not intended to limit the present invention. A person of ordinary skill in the art, without departing from the spirit and scope of the present invention, can make various modifications and variations. Therefore, the scope of the invention is defined in the claims.

What is claimed is:

1. An array substrate, comprising:
a base substrate;
a first metal layer disposed on the base substrate and including a gate region of a thin film transistor;
a gate insulating layer disposed on the first metal layer for separating the first metal layer from a second metal layer;
an active layer, a part of which is disposed on the gate insulating layer for forming a channel;
an ohmic contact layer disposed on the active layer;
the second metal layer disposed on the ohmic contact layer and including a drain region and a source region of the thin film transistor;
a first insulating layer disposed on the second metal layer; and
a third metal layer disposed on the first insulating layer and including a light protection region, wherein a position of the light protection region corresponds to a position of the channel, and an area of the light protection region projected on the base substrate is slightly larger an area of the channel projected on the base substrate.

2. The array substrate as claimed in claim 1, wherein the third metal layer further includes a pixel electrode, and the light protection region and the pixel electrode are obtained in a processing step.

3. The array substrate as claimed in claim 1, further comprising a transparent conductive layer disposed on the third metal layer and including a pixel electrode.

4. The array substrate as claimed in claim 1, further comprising a flat layer disposed on the third metal layer.

5. The array substrate as claimed in claim 1, wherein a material of the ohmic contact layer is silicon nitride.

6. An array substrate, comprising:
a base substrate;
a first metal layer disposed on the base substrate and including a gate region of a thin film transistor;
a gate insulating layer disposed on the first metal layer for separating the first metal layer from a second metal layer;
an active layer, a part of which is disposed on the gate insulating layer for forming a channel;
the second metal layer disposed on the active layer and including a drain region and a source region of the thin film transistor;
a first insulating layer disposed on the second metal layer; and
a third metal layer disposed on the first insulating layer and including a light protection region, wherein a position of the light protection region corresponds to a position of the channel.

7. The array substrate as claimed in claim 6, wherein the third metal layer further includes a pixel electrode, and the light protection region and the pixel electrode are obtained in a processing step.

8. The array substrate as claimed in claim 6, further comprising a transparent conductive layer disposed on the third metal layer and including a pixel electrode.

9. The array substrate as claimed in claim 6, wherein an area of the light protection region projected on the base substrate is slightly larger than an area of the channel projected on the base substrate

10. The array substrate as claimed in claim 6, further comprising a flat layer disposed on the third metal layer.

11. The array substrate as claimed in claim 6, further comprising an ohmic contact layer disposed between the active layer and the second metal layer.

12. The array substrate as claimed in claim 11, wherein a material of the ohmic contact layer is silicon nitride.

13. A liquid crystal display panel, comprising:
a color filter substrate disposed opposite an array substrate;
a liquid crystal layer disposed between the color filter substrate and the array substrate, and the array substrate including:
a base substrate;
a first metal layer disposed on the base substrate and including a gate region of a thin film transistor;
a gate insulating layer disposed on the first metal layer for separating the first metal layer from a second metal layer;
an active layer, a part of which is disposed on the gate insulating layer for forming a channel;
the second metal layer disposed on the active layer and including a drain region and a source region of the thin film transistor;
a first insulating layer disposed on the second metal layer; and
a third metal layer disposed on the first insulating layer and including a light protection region, wherein a position of the light protection region corresponds to a position of the channel.

14. The liquid crystal display panel as claimed in claim 13, wherein the third metal layer further includes a pixel electrode, and the light protection region and the pixel electrode are obtained in a processing step.

15. The liquid crystal display panel as claimed in claim 13, further comprising a transparent conductive layer disposed on the third metal layer and including a pixel electrode.

16. The liquid crystal display panel as claimed in claim 13, wherein an area of the light protection region projected on the base substrate is slightly larger than an area of the channel projected on the base substrate

17. The liquid crystal display panel as claimed in claim 13, further comprising a flat layer disposed on the third metal layer.

18. The liquid crystal display panel as claimed in claim 13, further comprising an ohmic contact layer disposed between the active layer and the second metal layer.

19. The liquid crystal display panel as claimed in claim 18, wherein a material of the ohmic contact layer is silicon nitride.
